(19) United States
(12) Patent Application Publication
(10) Pub. No.: US 2012/0256206 A1
(43) Pub. Date: Oct. 11, 2012

(54) LED MODULE WITH COOLING PASSAGE

(75) Inventor: Jang-Hyung Cho, Seoul (KR)

(73) Assignee: CEDIC CO., LTD., Seoul (KR)

(21) Appl. No.: 13/518,674

(22) PCT Filed: Dec. 10, 2010
(86) PCT No.: PCT/KR10/08842

§ 371 Date: Jun. 22, 2012

(30) Foreign Application Priority Data
Dec. 24, 2009 (KR) 10-2009-0130382

(51) Int. Cl. H01L 33/58

(52) U.S. Cl. 257/88; 257/E33.06

(57) ABSTRACT

An LED module with a cooling passage is disclosed. The LED module includes a light source unit having a plurality of LED's which provide light through an appropriate power supply, and one or more cooling units which form said cooling passage, which combine heat generated from the LEDs with ambient heat and discharges the combined heat in an opposite direction.

### TECHNICAL FIELD

The present invention relates to an LED lighting device, particularly an LED lighting device having a heat dissipation structure that can improve operational performance of a device with heat-generating units by ensuring a passage that passes heat generated from the heat-generating units to be discharged to the outside together with external air.

### BACKGROUND ART

In general, light emitting diode lamps (hereafter, referred to as ‘LED lighting device’) have the advantage in that economical efficiency is excellent because the efficiency of light to unit power is remarkably high in comparison to incandescent lamps and fluorescent lamps that are presently used.

That is, LEDs have the advantage in that they are eco-friendly and have a long life span because they generate a small amount of carbon and a small amount of heat, in addition to obtaining a desired amount of light from low voltage. Therefore, LEDs have been widely used for lighting devices, which can replace incandescent lamps and fluorescent lamps.

However, LED lighting devices have a problem in that it is difficult to obtain a desired amount of light due to heat from a plurality of LEDs when being used for a predetermined period of time and the life span of the LEDs rapidly decreases due to a gradual increase in the amount of generated heat when being continuously used.

In order to solve the problem, LED lighting devices have been configured to dissipate heat by attaching a heat sink made of metal to the rear side of an LED module (substrate) equipped with LEDs, in the related art.

A plurality of heat dissipation fins for dissipating heat and a plurality of holes (also called discharge holes or convection holes) for passing air and heat are formed in the heat sink of the related art.

The LED lighting devices of the related art have been configured to discharge heat by using contact with the atmosphere or discharge heat generated from the heat-generating units to the outside, using a way of generating natural convection by using lifting force due to the difference in temperature.

However, the LED modules used in the LED lighting devices of the related art are not provided with connection passages between the LEDs that generate heat and the heat sink that discharges heat.

That is, the heat generated from the LEDs is discharged to the outside only by contact between the substrate and the heat sink, such that the heat generated from the heat-generating units stops and cannot be quickly discharged to the outside.

Therefore, the heat generated from the heat-generating unit is not quickly discharged to the outside, such that it is impossible to prevent the heat-generating unit from continuously increasing in temperature, and accordingly, the life span or the function of the LEDs and the parts around are decreased, thus deteriorating the operational performance of the device.

### DISCLOSURE

### Technical Problem

Therefore, the present invention has been made in an effort to solve the problems in the related art and the object of the present invention is to provide an LED module that allows heat generated from LEDs to be quickly discharge to the outside without stopping, by ensuring a passage that passes heat generated from the heat-generating units to be discharged to the outside together with external air.

### Technical Solution

An exemplary embodiment of the present invention provides an LED module with a cooling passage of the present invention includes: a light source unit equipped with a plurality LEDs emitting light by supplying with power; and one or a plurality of cooling unit formed at the light source unit to form passages for discharging heat generated from the LEDs in the opposite directions together with external air. In this configuration, it is preferable that the cooling unit includes a first cooling hole and a second cooling hole and the light source unit includes an LED substrate equipped with the LEDs on the underside and having the first cooling hole formed through the center, and a condensing lens unit fastened to the underside of the LED substrate to diffuse light from the LEDs through lenses and having the second cooling hole formed to be connected with the first cooling hole.

Further, it is preferable that the cooling unit further includes a third hole, and a lens cover having seating holes that the lenses pass and the third cooling hole formed to be connected with the second cooling hole is further disposed under the condensing lens unit.

Further, it is preferable that a cover-fastening member extending upward and surrounding the third cooling hole to form one passage, and having a plurality of locking protrusions protruding outward along the upper end is further disposed on the top of the lens cover, and the locking protrusions are locked on the first cooling hole through the second cooling hole.

Meanwhile, the cooling unit is formed in any one of a circle, an ellipse, and a polygon. Further, it is preferable that the cooling unit is sized to be 20 to 80% of the size of the LED substrate.

Meanwhile, it is preferable that the cooling unit further has a plurality of sub-cooling grooves along the inner circumference.

In this configuration, it is preferable that the sub-cooling grooves are selectively arranged in the installation direction of the LEDs. Further, it is preferable that the length and width of the sub-cooling grooves depend on the amount of heat from the LEDs.

Meanwhile, a heat sink that discharges heat transferred from the light source unit to the outside may be further disposed above the light source unit.

In this configuration, the heat sink may have an upper cooling hole that forms one passage with the cooling unit, a cover-fastening member that extends upward while surrounding the third cooling hole to form one passage and has a plurality of locking protrusions protruding outward along the upper end may be further disposed on the top of the lens cover, and the locking protrusions may be locked on the upper cooling hole through the second cooling hole and the first cooling hole.

In addition, the LED substrate may have one or more first through-holes, the heat sink may further have second through-holes connected with the first through-holes, and the LED substrate may further include hollow heat transfer members being in close contact with the rear sides of the LEDs through the second through-holes and the first through-holes, and blocking members disposed between the heat transfer members and the LEDs to prevent electric connection.

### Advantageous Effects

As described above, the present invention makes it possible to quickly discharge heat generated from heat-generating units to the outside together with external air by improving cooling performance, by forming passages in an LED module. Accordingly, it is possible to prevent the functions and life spans of LEDs disposed on a substrate and the parts around, from being reduced.

### DESCRIPTION OF DRAWINGS

FIG. 1 is a perspective disassembly view of an LED module with a cooling passage according to the present invention.

FIG. 2 is a perspective disassembly view showing a heat sink and a power module in order to show when the LED module with a cooling passage according to the present invention is installed.

FIG. 3 is a plan view showing the heat sink and the power module in order to show when the LED module with a cooling passage according to the present invention is installed.

FIG. 4 is a front cross-sectional view taken along line A-A which shows the heat sink and the power module in order to show when the LED module with a cooling passage according to the present invention is installed.

FIG. 5 is a perspective bottom view showing an LED substrate to exemplarily showing when sub-cooling grooves are further formed at the cooling unit of the LED module with a cooling passage according to the present invention.

FIG. 6 is a perspective view showing the heat sink with heat dissipation fins deployed, to show when the LED modules with a cooling passage according to the present invention is further equipped with heat transfer members.

FIG. 7 is a front cross-sectional view showing when a condensing lens unit and a lens cover have been combined in the LED module with a cooling passage according to the present invention.

FIG. 8A is a view schematically showing temperature distribution according to the diameter of a cooling hole when heat is discharged by an integrated-type heat sink according to the present invention.

FIG. 8B is a view schematically showing velocity distribution according to the diameter of the cooling hole when heat is discharged by the integrated-type heat sink according to the present invention.

FIG. 9 is a view comparing temperature distributions when a cooling hole is formed, as in the present invention, with when a cooling hole is not formed, as in the related art, in order to show a process of discharging heat in the LED module with a cooling passage according to the present invention.

### BEST MODE

Preferred embodiments of the present invention will be described hereafter in detail with reference to the accompanying drawings.

Terminologies defined in description of the present invention are defined in consideration of the functions in the present invention and should not be construed as limiting the technical components of the present invention.

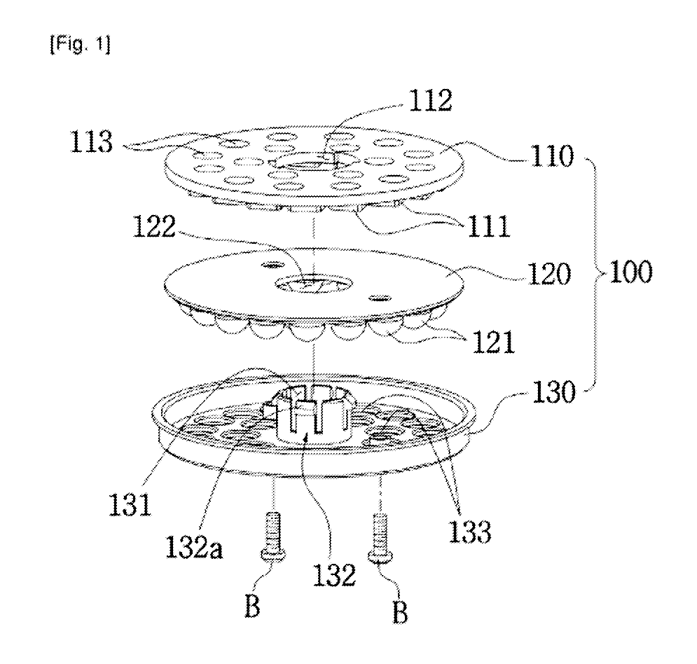

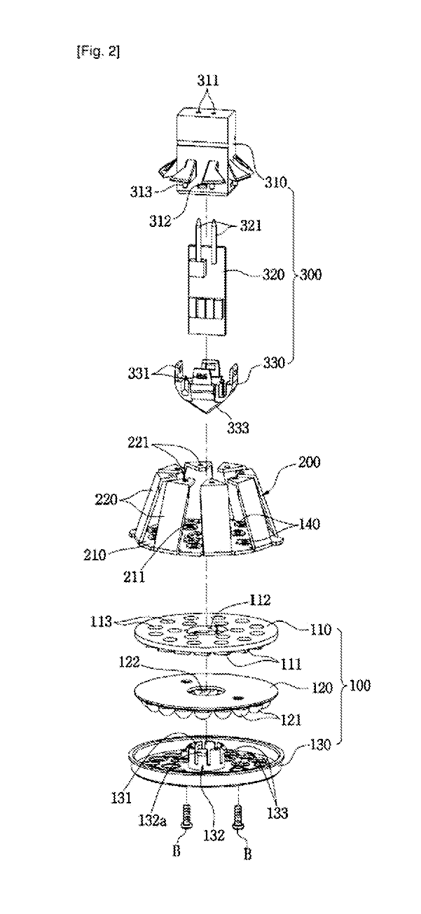

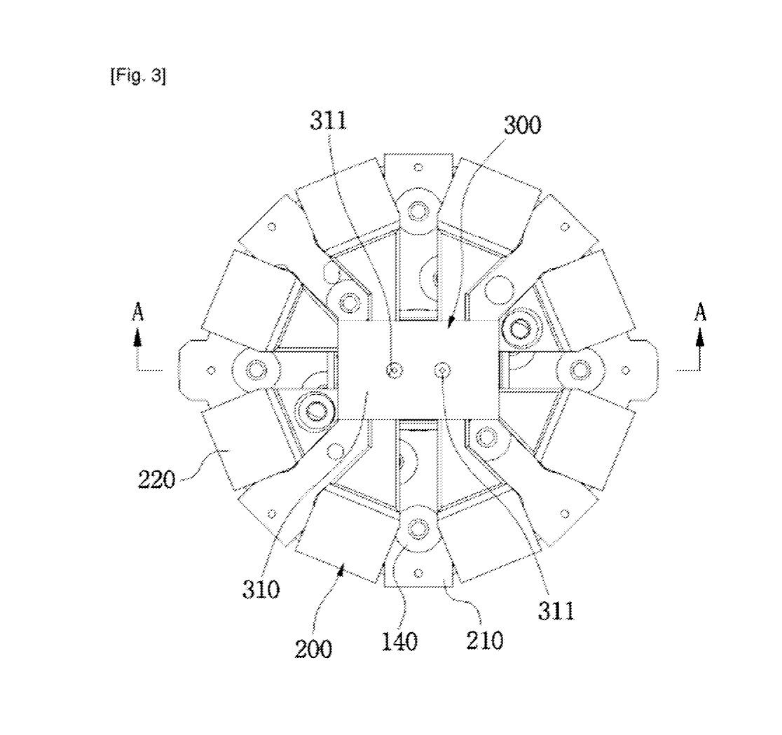

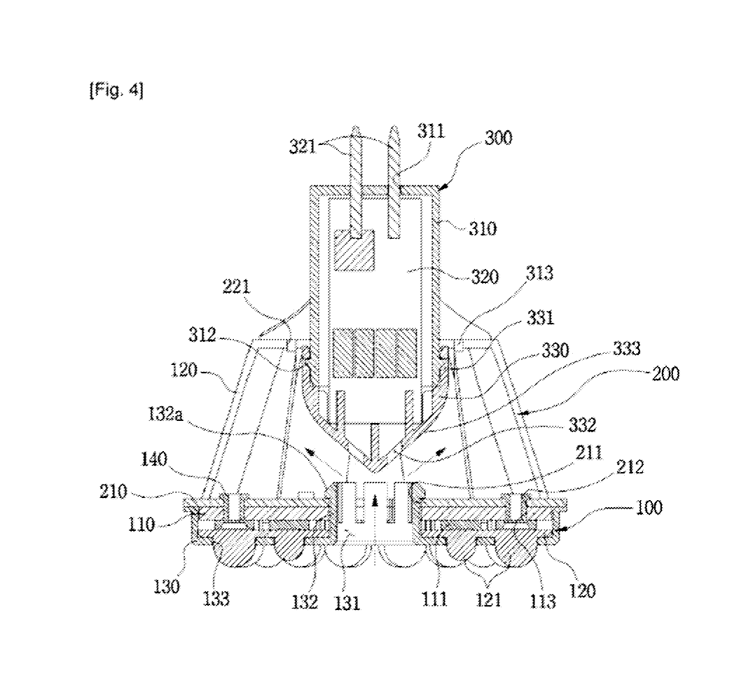

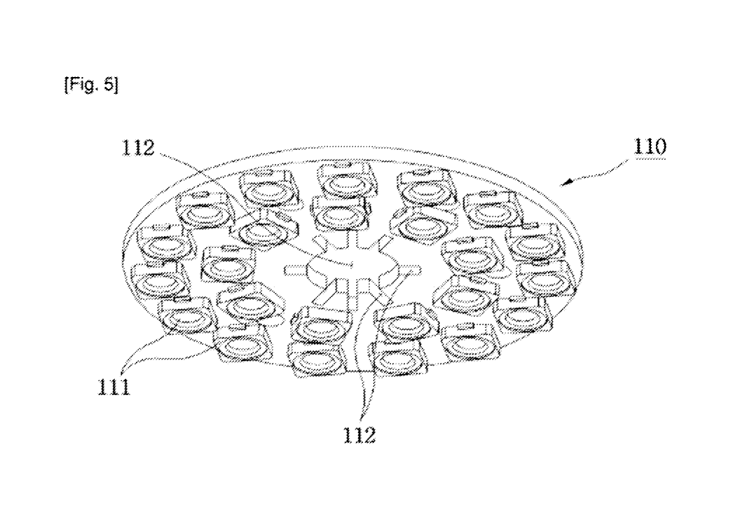

FIG. 1 is a perspective disassembly view of an LED module with a cooling passage according to the present invention, FIG. 2 is a perspective disassembly view showing a heat sink and a power module in order to show when the LED module with a cooling passage according to the present invention is installed, FIG. 3 is a plan view showing the heat sink and the power module in order to show when the LED module with a cooling passage according to the present invention is installed, FIG. 4 is a front cross-sectional view taken along line A-A which shows the heat sink and the power module in order to show when the LED module with a cooling passage according to the present invention is installed, and FIG. 5 is a perspective bottom view showing an LED substrate to exemplarily show when sub-cooling grooves are further formed at the cooling unit of the LED module with a cooling passage according to the present invention.

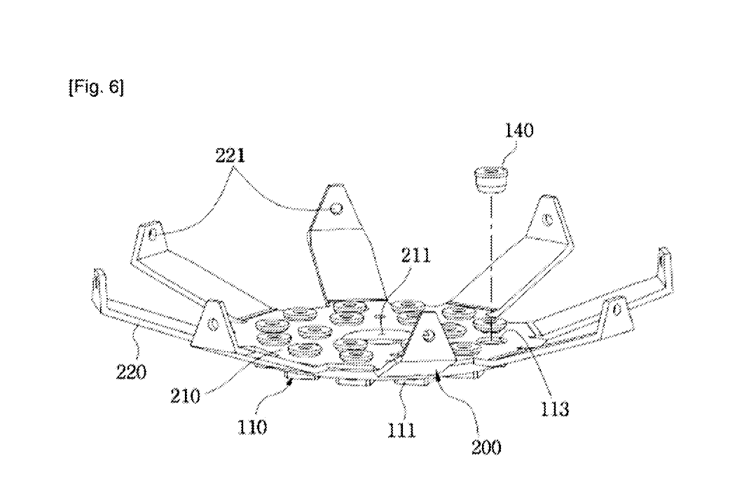

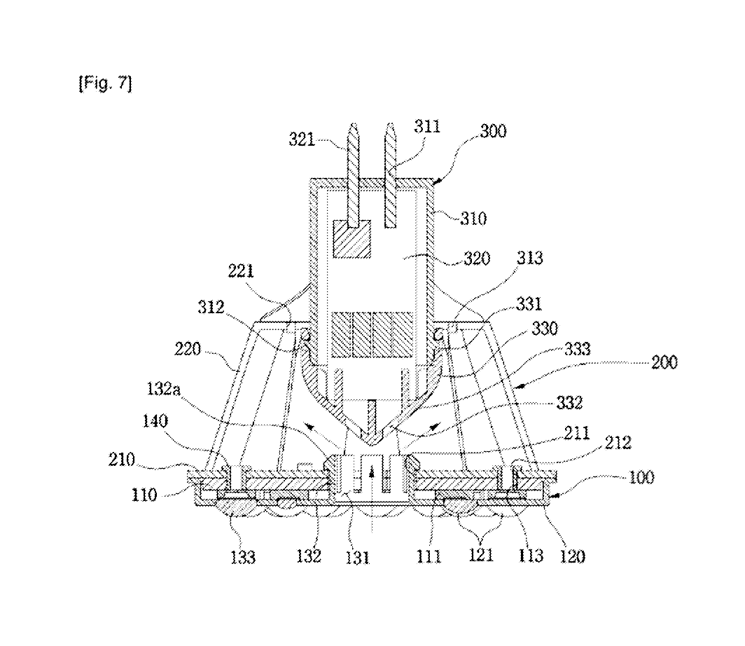

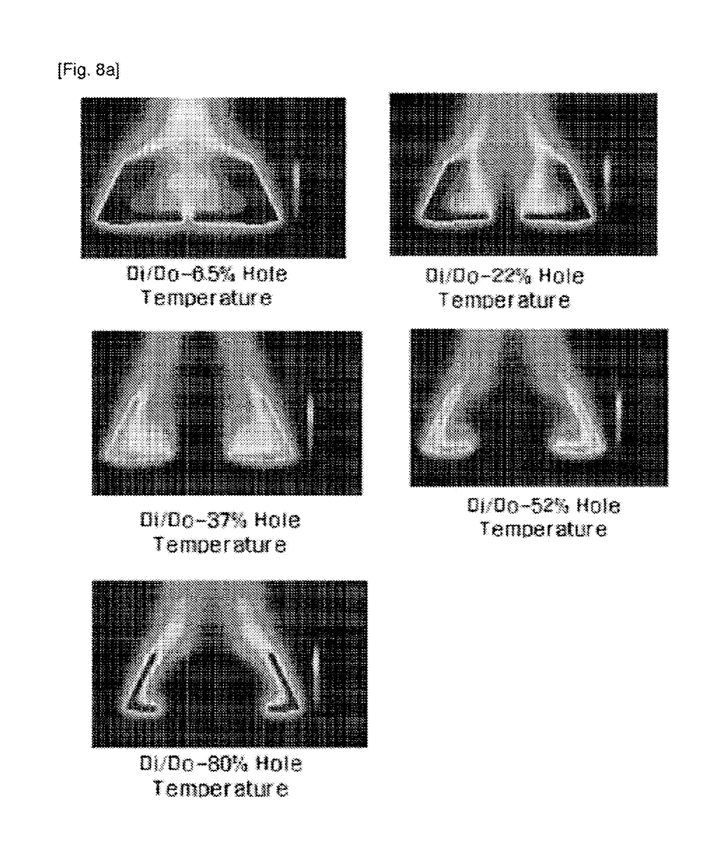

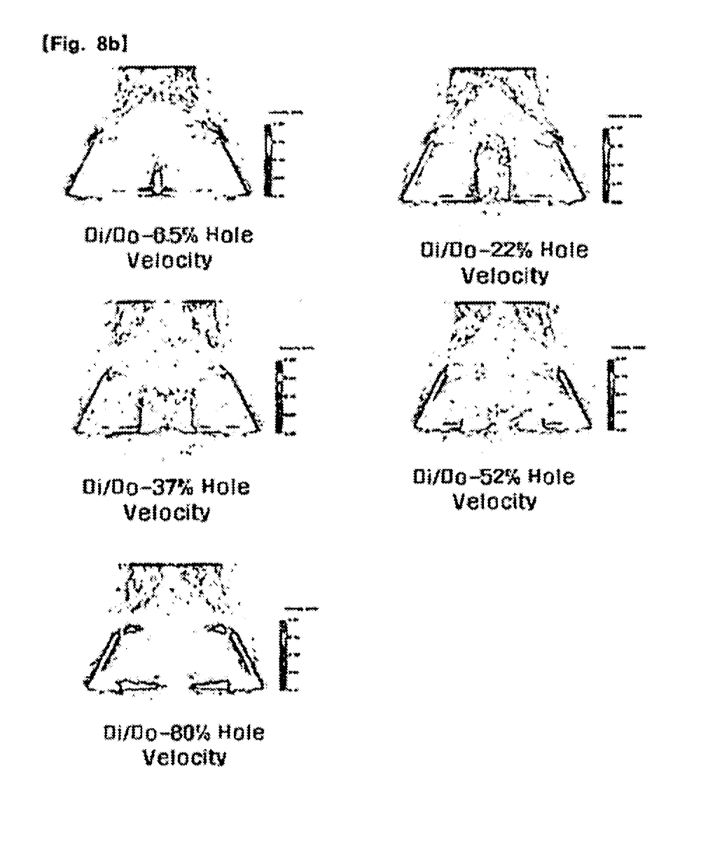

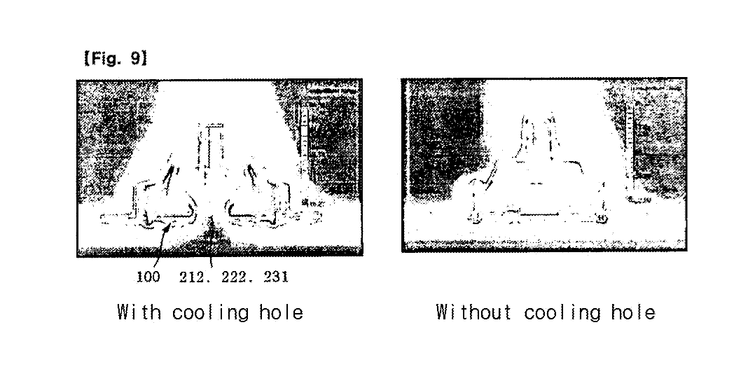

Further, FIG. 6 is a perspective view showing the heat sink with heat dissipation fins deployed, to show when the LED modules with a cooling passage according to the present invention is further equipped with heat transfer members, FIG. 7 is a front cross-sectional view showing when a condensing lens unit and a lens cover have been combined in the LED module with a cooling passage according to the present invention, FIG. 8A is a view schematically showing temperature distribution according to the diameter of a cooling hole when heat is discharged by an integrated-type heat sink according to the present invention, FIG. 8B is a view schematically showing velocity distribution according to the diameter of the cooling hole when heat is discharged by the integrated-type heat sink according to the present invention, and FIG. 9 is a view comparing temperature distributions when a cooling hole is formed, as in the present invention, with when a cooling hole is not formed, as in the related art, in order to show a process of discharging heat in the LED module with a cooling passage according to the present invention.

As shown in FIGS. 1 to 4, an LED module 100 with a cooling passage of the present invention includes a light source unit equipped with a plurality LEDs 111 emitting light by being supplied with power, and one or a plurality of cooling unit formed at the light source unit to form passages for discharging heat generated from the LEDs 111 in the opposite directions together with external air. The cooling unit includes a first cooling hole 112, a second cooling hole 122, and a third cooling hole 131.

The light source unit includes an LED substrate 110 equipped with the LEDs 111 on the underside and having the first cooling hole 112 vertically formed through the center, and a condensing lens unit 120 fastened to the underside of the LED substrate 110 to diffuse light generated from the LEDs 111 through lenses 121 and having the second cooling hole 122 vertically formed to be connected with the first cooling hole 112.

In this configuration, it is preferable to arrange the LEDs 111 at regular intervals circumferentially around the first cooling hole 112 formed at the center, on the underside of the LED substrate 110.

Further, a lens cover 130 may be further disposed under the condensing lens unit 120, and has seating holes 133 vertically formed to pass and seat the lenses 121 and the third cooling hole 131 vertically formed to be connected (communicate) with the second cooling hole 122 of the condensing lens unit 120. That is, the first, second, and third cooling holes 112, 122, and 131 form one vertical passage such that external air and heat generated from heat-generating units can flow inside from below and be discharged upward.

The seating holes 133 may be formed to have a diameter equal to or larger than the circumferences of the lenses 121 such that the lenses 121 can pass through them.

Further, the cover-fastening member 132 extending upward and surrounding the third cooling hole 131 may be formed on the top of the lens cover 130. A plurality of locking protrusions 132a is formed along the circumference at the upper end of the cover-fastening member 132 to protrude outward.

The locking protrusions 132a are locked on the first cooling hole 112 through the second cooling hole 122. Accordingly, the LED substrate 110, the condensing lens unit 120, and the lens cover 130 can be integrally fixed.

Further, the lens cover 130, the condensing lens unit 120, and the LED substrate 110 may be fastened by a plurality of fasteners B. That is, when the cover-fastening member 132 is mounted on the lens cover 130, the space inside the cover-fastening member 132 becomes the third cooling hole 131 and the space inside the third cooling hole 131 forms one vertical passage for taking external air inside and discharging heat.

For this configuration, it is preferable that the outer diameter of the cover-fastening member 132 is the same as the diameters of the first, second, and third cooling holes 112, 122, and 131, which are described above.

Meanwhile, as shown in FIG. 6, the condensing lens unit 120 may simultaneously perform the functions of a lens and a cover by being fastened to the underside of the LED substrate 110 by the cover-fastening member 132 that is described below. In this case, the cover-fastening member 132 may be formed on the condensing lens unit 120 to surround the second lower cooling hole 122.

One passage formed by the first, second, and third cooling holes 112, 122, and 131 is formed preferably in a circular shape, but may be formed in any one of an ellipse and a polygon, which are not shown.

Further, it is preferable that the inner diameters of the first, second, and third cooling holes 112, 122, 131 are 6.5 to 80% of the outer diameters of the LED substrate 110 and the condensing lens unit 120.

For example, FIGS. 8A and 8B show when the inner diameters of the first, second, and third cooling holes 112, 122, and 131 are set at 6.5%, 22%, 37%, 52%, and 80% of the outer diameters of the LED substrate 110 and the condensing lens unit 120 and then external air flowing inside through the cooling holes and heat generated from a heat-generating unit are discharged upward.

The red parts are where temperature is the highest and velocity is the highest and the blue parts are where temperature is the lowest and velocity is the lowest.

That is, referring to FIG. 8A, it can be seen that as the external air flows inside through the cooling hole formed at the center while air and heat is discharged, the temperature rapidly decreases toward the upper portion. Further, referring to FIG. 8B, it can be seen that the velocity increases toward the upper portion.

Meanwhile, as in FIG. 5, a plurality of sub-cooling grooves 112a may be further formed along the inner circumferences of the first, second, and third cooling holes 112, 122, and 131.

The sub-cooling grooves 112a may be selectively arranged in the installation direction of the LEDs 111, and the length and width of the sub-cooling grooves 112a may depend on the amount of heat generated by the LEDs 111. Therefore, the sub-cooling grooves 112a have orientation to the portions where the LEDs 211 are disposed, such that they have an effect of intensively cooling the portions where a large amount of heat is generated

The LED module 100 described above, in accordance with the present invention, may be organically combined with a heat sink 200 that discharges heat generated from the heat-generating units to the outside and the power module that supplies power to the LED module 100.

Obviously, the configurations described herein are only examples of preferable installation states of the LED module 100 and it should be understood that the present invention may be achieved in various ways without being limited thereto.

As shown in FIGS. 2 to 4, the heat sink 200 may include a heat dissipation plate 210 having an upper cooling hole 211 vertically formed through the heat dissipation plate 210 and a plurality of heat dissipation fins 220 integrally bent upward along the edge of the heat dissipation plate 210 and having a predetermined length upward. In this configuration, the heat dissipation fins 220 may be arranged at predetermined distances or in contact with each other.

Insertion holes 221 are vertically formed through the tops of the heat dissipation fins 120 such that a power module 300 can be combined. Preferably, it may be possible to bend the upper ends of the heat dissipation fins 220 toward the center of the heat dissipation plate 220 to form flat surfaces and then vertically form the insertion holes 221 through the flat surfaces.

In addition, as shown in FIG. 6, at least one or more first through-holes 113 may be formed at the LED substrate 110 and second through-holes 212 connected with the first through-holes 113 may be formed at the heat dissipation plate 210.

Further, heat transfer members 140 being in close contact with the rear sides of the LEDs 111 through the second through-holes 212 and the first through-holes 113, and blocking members (not shown) disposed between the heat transfer members 140 and the LEDs to prevent electric connection may be further provided to transfer the heat from the LEDs 111 to the heat dissipation plate 210.

In this configuration, the tops of the heat transfer members 240 may extend outward to be locked on the first through-holes 113.

Further, the heat transfer members 140 are preferably made of copper or the like to transfer heat well, but various kinds of conductive metals may be selectively used. Further, the blocking members (not shown) may be made of synthetic resin that is not electrically conductive, in a tape shape to prevent electric connection.

That is, the heat transfer members 140 can directly transmit the heat generated from the LEDs 111 to the heat dissipation plate 210 without being electrically connected with the LEDs 111. Therefore, it is possible to further improve the performance of discharging heat.

The power module 300 includes an upper holder 310 having terminal holes 311 at the upper portion and seated on the upper ends of the heat dissipation fins 220, a power substrate 320 fitted in the upper holder 310 from below such that connection terminals 321 disposed at the upper portion are inserted in the terminal holes 311 to be exposed upward, and a lower holder 330 fitted on the lower portion of the upper holder 310 and supporting and preventing the power substrate 320 from being separated outward.

In this structure, a plurality of locking protrusions 312 protrudes outward from the sides of the upper holder 310. Further, inclined surfaces (not given a reference number) that are inclined upward and outward from the ends connected to the upper holder 310 may be formed on the undersides of the locking protrusions 312.

Further, a plurality of locking holes 331 is horizontally formed through the upper portion of the lower holder 330 that is fitted on the upper holder 310 to fit the locking protrusions 312 therein. Further, a plurality of insertion protrusions 313, which protrude outward above and adjacent to the locking protrusions 312 and then extend downward, is further formed on the sides of the upper holder 310.

That is, the upper ends with the locking holes 331 of the lower holder 330 open outward while sliding on the inclined surfaces formed on the undersides of the locking protrusions 312 and are restored by elastic restoring force at the ends of the inclined surfaces, such that the locking protrusions 312 are fitted. Therefore, the upper holder 310 and the lower holder 330 can be firmly combined.

Further, when the power module 300 is fixed on the upper portions of the heat sink 200, the insertion protrusions 313 of the upper holder 310 are inserted into the insertion holes 221 formed at the tops of the heat dissipation fins 220.

Meanwhile, at least one or more cable holes 332 may be formed through bottom of the lower holder 330 to pass cables (not shown). That is, cables (not shown) extending from the power substrate 320 are electrically connected to the LED substrate 110 through the cable holes 332.

Guide surfaces 333 narrowing downward may be formed on the underside of the lower holder 330 to guide the flow of air. That is, the guide surfaces 333 are narrow at the lower ends, such that the air flowing from below can be guided to quickly flow upward without stopping.

FIG. 9 shows the process of discharging heat from the LED module 100 with a cooling passage according to the present invention.

That is, it can be seen that as cold external air flows inside through the passage, the internal temperature of the LED module 100 rapidly decreases, when there are cooling holes, as in the present invention. On the contrary, it can be seen that the internal temperature of the LED module 100 is high, when there is no cooling hole.

As a result, the LED module 100 according to the present invention can quickly discharge the heat generated from the heat-generating units to the outside together with external air by improving cooling performance, by forming the passage. Therefore, it is possible to prevent the functions and the life spans of the LEDs 111 disposed on the LED substrate 110 and the parts around from being reduced, and improve the operational performance of the device.

Although the spirit of the LED module 100 with a cooling passage according to the present invention is described above with reference to the accompanying drawings, this is an example for describing the most preferable embodiment of the present invention and does not limit the present invention.

Therefore, it is apparent that the present invention may be modified and copied in dimensions, shape, and structure by those skilled in the art without departing from the scope of the present invention and those modifications and copies are included in the scope of the present invention.

1. An LED module comprising:
a light source unit equipped with a plurality LEDs emitting light by being supplied with power; and
one or a plurality of cooling unit formed at the light source unit to form passages for discharging heat generated from the LEDs in the opposite directions together with external air

2. The LED module of claim 1, wherein the cooling unit includes a first cooling hole and a second cooling hole, and
the light source unit includes an LED substrate equipped with the LEDs on the underside and having the first cooling hole formed through the center, and a condensing lens unit fastened to the underside of the LED substrate to diffuse light from the LEDs through lenses and having the second cooling hole formed to be connected with the first cooling hole.

3. The LED module of claim 2, wherein the cooling unit further includes a third hole, and a lens cover having seating holes that the lenses pass and the third cooling hole formed to be connected with the second cooling hole is further disposed under the condensing lens unit.

4. The LED module of claim 3, wherein a cover-fastening member extending upward and surrounding the third cooling hole to form one passage, and having a plurality of locking protrusions outward along the upper end is further disposed on the top of the lens cover, and the locking protrusions are locked on the first cooling hole through the second cooling hole.

5. The LED module of claim 3, wherein the cooling unit is formed in any one of a circle, an ellipse, and a polygon.

6. The LED module of claim 3, wherein the inner diameter of the cooling unit is 6.5 to 80% of the outer diameters of the LED substrate and the condensing lens unit.

7. The LED module of claim 3, wherein the cooling unit further has a plurality of sub-cooling grooves along the inner circumference.

8. The LED module of claim 7, wherein the sub-cooling grooves are selectively arranged in the installation direction of the LEDs.

9. The LED module of claim 8, wherein the length and width of the sub-cooling grooves depend on the amount of heat from the LEDs.

10. The LED module of claim 3, wherein a heat sink that discharges heat transferred from the light source unit to the outside is further disposed above the light source unit.

11. The LED module of claim 10, wherein the heat sink has an upper cooling hole that forms one passage with the cooling unit, a cover-fastening member that extends upward while surrounding the third cooling hole to form one passage and has a plurality of locking protrusions protruding outward along the upper end is disposed on the top of the lens cover, and the locking protrusions are locked on the upper cooling hole through the second cooling hole and the first cooling hole.

12. The LED module of claim 11, wherein the LED substrate has one or more first through-holes, the heat sink further has second through-holes connected with the first through-holes, and the LED substrate further includes hollow heat transfer members being in close contact with the rear sides of the LEDs through the second through-holes and the first through-holes, and blocking members disposed between the heat transfer members and the LEDs to prevent electric connection.
